(19) United States
(12) Patent Application Publication
(10) Pub. No.: US 2017/0053947 A1
(43) Pub. Date: Feb. 23, 2017

(54) THIN-FILM TRANSISTOR, SEMICONDUCTOR UNIT, AND ELECTRONIC APPARATUS

(71) Applicant: JOLED INC., Chiyoda-ku (JP)

(72) Inventors: Atsuya MAKITA, Tokyo (JP); Atsuhito MURAI, Tokyo (JP)

(73) Assignee: JOLED INC., Chiyoda-ku (JP)

(21) Appl. No.: 15/234,557

(22) Filed: Aug. 11, 2016

(30) Foreign Application Priority Data
Aug. 21, 2015 (JP) 2015-163783

(51) Int. Cl. H01L 27/12; H01L 29/45; H01L 29/417; H01L 29/423; H01L 29/786

(52) U.S. Cl. CPC H01L 27/1225; H01L 29/42384; H01L 29/78696; H01L 29/7869; H01L 29/78606; H01L 29/41733; H01L 29/45

(57) ABSTRACT

A thin-film transistor includes an oxide semiconductor layer, a gate insulating film, a gate electrode, and a source-drain electrode. The oxide semiconductor layer includes a channel region and a low-resistance region that has an electric resistance lower than an electric resistance of the channel region. The gate insulating film is provided on the oxide semiconductor layer. The gate electrode is provided on the gate insulating film and opposed to the channel region of the oxide semiconductor layer. The gate electrode includes a first electrode layer and a second electrode layer in order from the gate insulating film. The first electrode layer has a first width that is along a channel length and greater than a second width of the second electrode layer along the channel length. The source-drain electrode is electrically coupled to the low-resistance region of the oxide semiconductor layer.

### CROSS REFERENCE TO RELATED APPLICATIONS

This application claims the benefit of Japanese Priority Patent Application JP2015-163783 filed Aug. 21, 2015, the entire contents of which are incorporated herein by reference.

### BACKGROUND

The disclosure relates to a thin-film transistor that utilizes an oxide semiconductor layer, and a semiconductor unit and an electronic apparatus that include the thin-film transistor.

With the progress in larger screen and higher-speed driving of active-matrix-driven displays, there is an increasing demand in recent years for characteristics of thin-film transistors (TFTs) used for driving of the active-matrix-driven displays. Among the thin-film transistors, a thin-film transistor that utilizes an oxide semiconductor for a channel layer allows for higher mobility and larger area, resulting in an active development of the thin-film transistor that includes the oxide semiconductor. For example, reference is made to Japanese Unexamined Patent Application Publication No. 2012-33836 and N. Morosawa et al., Journal of SID, Vol. 20, Issue 1, pp. 47-52, 2012.

To achieve the higher-speed driving of the displays, it is preferable that an amount of current to be supplied to the thin-film transistor, i.e., the mobility, be increased. It is also preferable that a parasitic capacitance generated at the thin-film transistor be decreased. These make it possible to prevent an occurrence of a signal delay or any other concern.

To achieve the decrease in parasitic capacitance, Morosawa proposes a top-gate thin-film transistor having a so-called self-aligned structure. The thin-film transistor proposed by Morosawa includes a gate electrode provided on an oxide semiconductor layer with a gate insulating film interposed in between. The gate electrode is utilized as a mask to form the gate insulating film. The oxide semiconductor layer also includes a region non-opposed to the gate electrode, i.e., a region exposed from the gate electrode. The region non-opposed to the gate electrode is made low in resistance as a low-resistance region, and a source-drain electrode is electrically coupled to the low-resistance region.

### SUMMARY

A manufacturing process of a thin-film transistor that utilizes an oxide semiconductor involves a large number of annealing processes. The annealing processes cause a channel region to be low in resistance, i.e., expand a low-resistance region, and generate a parasitic capacitance. The generation of the parasitic capacitance may lead to a decrease in switching performance as a thin-film transistor.

It is desirable to provide a thin-film transistor, a semiconductor unit, and an electronic apparatus that make it possible to reduce a parasitic capacitance.

A thin-film transistor according to an illustrative embodiment of the disclosure includes: an oxide semiconductor layer including a channel region and a low-resistance region that has an electric resistance lower than an electric resistance of the channel region; a gate insulating film provided on the oxide semiconductor layer; a gate electrode provided on the gate insulating film and opposed to the channel region of the oxide semiconductor layer, in which the gate electrode includes a first electrode layer and a second electrode layer in order from the gate insulating film, and the first electrode layer has a first width that is along a channel length and greater than a second width of the second electrode layer along the channel length; and a source-drain electrode electrically coupled to the low-resistance region of the oxide semiconductor layer.

A semiconductor unit according to an illustrative embodiment of the disclosure is provided with a drive circuit. The drive circuit is provided with a thin-film transistor. The thin-film transistor includes: an oxide semiconductor layer including a channel region and a low-resistance region that has an electric resistance lower than an electric resistance of the channel region; a gate insulating film provided on the oxide semiconductor layer; a gate electrode provided on the gate insulating film and opposed to the channel region of the oxide semiconductor layer, in which the gate electrode includes a first electrode layer and a second electrode layer in order from the gate insulating film, and the first electrode layer has a first width that is along a channel length and greater than a second width of the second electrode layer along the channel length; and a source-drain electrode electrically coupled to the low-resistance region of the oxide semiconductor layer.

An electronic apparatus according to an embodiment of the disclosure is provided with a drive circuit. The drive circuit is provided with a thin-film transistor. The thin-film transistor includes: an oxide semiconductor layer including a channel region and a low-resistance region that has an electric resistance lower than an electric resistance of the channel region; a gate insulating film provided on the oxide semiconductor layer; a gate electrode provided on the gate insulating film and opposed to the channel region of the oxide semiconductor layer, in which the gate electrode includes a first electrode layer and a second electrode layer in order from the gate insulating film, and the first electrode layer has a first width that is along a channel length and greater than a second width of the second electrode layer along the channel length; and a source-drain electrode electrically coupled to the low-resistance region of the oxide semiconductor layer.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a cross-sectional view of a configuration of a thin-film transistor according to one embodiment of the disclosure.

FIG. 2A is a cross-sectional view of a detailed configuration of a semiconductor layer, a gate insulating film, and a gate electrode illustrated in FIG. 1.

FIG. 2B is a plan view of the detailed configuration of the semiconductor layer, the gate insulating film, and the gate electrode illustrated in FIG. 1.

FIG. 3 is a cross-sectional view of a process in a method of manufacturing the thin-film transistor illustrated in FIG. 1.

FIG. 4 is a cross-sectional view of a process subsequent to the process illustrated in FIG. 3.

FIG. 5A is a cross-sectional view of a process subsequent to the process illustrated in FIG. 4.

FIG. 5B is a cross-sectional view of a process subsequent to the process illustrated in FIG. 5A.

FIG. 5C is a cross-sectional view of a process subsequent to the process illustrated in FIG. 5B.

FIG. 5D is a cross-sectional view of a process subsequent to the process illustrated in FIG. 5C.

FIG. 6A is a cross-sectional view of a process subsequent to the process illustrated in FIG. 5D.

FIG. 6B is a cross-sectional view of a process subsequent to the process illustrated in FIG. 6A.

FIG. 6C is a cross-sectional view of a process subsequent to the process illustrated in FIG. 6B.

FIG. 7 is a cross-sectional view of a process subsequent to the process illustrated in FIG. 6C.

FIG. 8 is a cross-sectional view of a process subsequent to the process illustrated in FIG. 7.

FIG. 9A is a cross-sectional view of a configuration of a thin-film transistor according to a comparative example.

FIG. 9B is a cross-sectional view for describing an effect of the thin-film transistor illustrated in FIG. 1.

FIG. 10 is a cross-sectional view of a configuration of a thin-film transistor according to modification example 1.

FIG. 11A is a cross-sectional view of a process in a method of manufacturing the thin-film transistor illustrated in FIG. 10.

FIG. 11B is a cross-sectional view of a process subsequent to the process illustrated in FIG. 11A.

FIG. 11C is a cross-sectional view of a process subsequent to the process illustrated in FIG. 11B.

FIG. 12 is a cross-sectional view of a process in a method of forming a gate electrode according to modification example 2.

FIG. 13A is a cross-sectional view of a process subsequent to the process illustrated in FIG. 12.

FIG. 13B is a cross-sectional view of a process subsequent to the process illustrated in FIG. 13A.

FIG. 13C is a cross-sectional view of a process subsequent to the process illustrated in FIG. 13B.

FIG. 13D is a cross-sectional view of a process subsequent to the process illustrated in FIG. 13C.

FIG. 14A is a cross-sectional view of a configuration of a thin-film transistor according to modification example 3-1.

FIG. 14B is a cross-sectional view of a configuration of a thin-film transistor according to modification example 3-2.

FIG. 14C is a cross-sectional view of a configuration of a thin-film transistor according to modification example 3-3.

FIG. 15 is a block diagram illustrating a configuration of a semiconductor unit (a display unit) according to a first application example.

FIG. 16 is a block diagram illustrating a configuration of the semiconductor unit (an image pickup unit) according to the first application example.

FIG. 17 is a block diagram illustrating a configuration of an electronic apparatus according to a second application example.

### DETAILED DESCRIPTION

In the following, some example embodiments of the disclosure are described in detail in the following order with reference to the accompanying drawings.

1. Example Embodiment (an example of a thin-film transistor that includes a gate electrode in which a first electrode layer and a second electrode layer having different widths from each other are laminated)
2. Modification Example 1 (an example in which the first electrode layer of the gate electrode includes a thin-film region)
3. Modification Example 2 (an example of an alternative method of forming the gate electrode)
4. Modification Examples 3-1 to 3-3 (alternative configuration examples of the gate electrode)
5. First Application Example (examples of a semiconductor unit)
6. Second Application Example (an example of an electronic apparatus)

Note that the following description is directed to illustrative examples of the technology and not to be construed as limiting to the technology. Further, factors including, without limitation, arrangement, dimensions, and a dimensional ratio of elements illustrated in each drawing are illustrative only and not to be construed as limiting to the technology.

### Example Embodiment

### Configuration

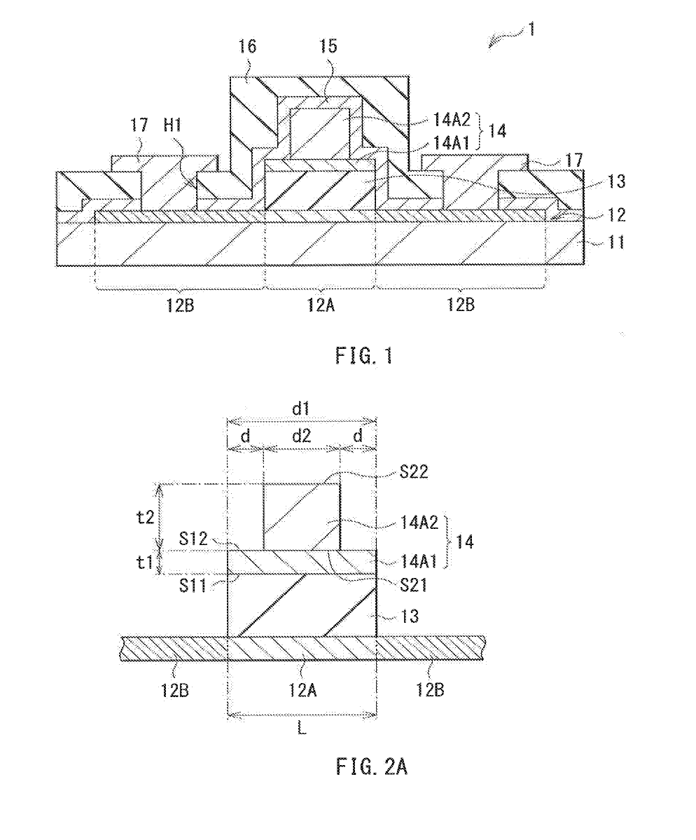

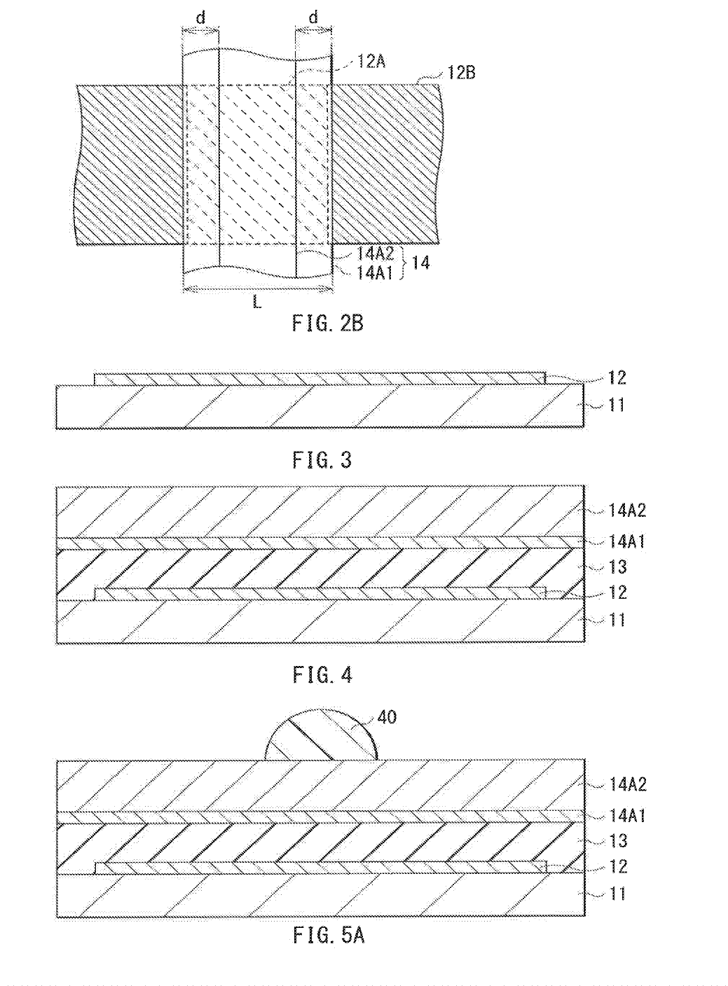

FIG. 1 illustrates a cross-sectional configuration of a thin-film transistor (a thin-film transistor 1) according to an example embodiment of the disclosure. FIG. 2A and FIG. 2B each illustrate a detailed configuration of a semiconductor layer, a gate insulating film, and a gate electrode, in which FIG. 2A illustrates a cross-sectional configuration thereof and FIG. 2B illustrates a plan configuration thereof. The thin-film transistor 1 may be a top-gate thin-film transistor having a so-called self-aligned structure. The thin-film transistor 1 has a semiconductor layer 12 in a selective region on a substrate 11. The semiconductor layer 12 may serve as an oxide semiconductor layer in one embodiment. The thin-film transistor 1 also has a gate insulating film 13 provided on the semiconductor layer 12, and a gate electrode 14 provided in a predetermined region on the gate insulating film 13. The predetermined region may be a region of the gate insulating film 13 which is opposed to the channel region 12A to be described later. Further, the thin-film transistor 1 may have a high-resistance film 15 and an interlayer insulating film 16 so provided in this order as to cover the semiconductor layer 12, the gate insulating film 13, and the gate electrode 14. The high-resistance film 15 and the interlayer insulating film 16 may have a contact hole H1 that faces a part of the semiconductor layer 12, i.e., faces a low-resistance region 12B to be described later. The thin-film transistor 1 has a source-drain electrode 17 so provided on the interlayer insulating film 16 that the contact hole H1 is filled with the source-drain electrode 17.

The substrate 11 may be made of a material such as glass, quartz, silicon, and a resin material. Non-limiting examples of the resin material may include polyethylene terephthalate (PET), polyimide (PI), polycarbonate (PC), and polyethylene napthalate (PEN). In one embodiment where the substrate 11 is made of the resin material, a barrier film may be provided on the substrate 11. Non-limiting examples of the barrier film may include a silicon oxide film (SiOx), a silicon nitride film (SiNx), and an aluminum oxide film (AlOx). Alternatively, a member in which a film made of an insulating material is formed on a metal substrate may be used as the substrate 11. The metal substrate may be a stainless steel (SUS) substrate without limitation.

The semiconductor layer 12 may be patterned on the substrate 11, and includes a channel region (serving as an active layer) 12A and the low-resistance region 12B. The low-resistance region 12B has an electric resistance lower than that of the channel region 12A. The semiconductor layer 12 may be made of an oxide semiconductor that contains, as a main component, an oxide of one or more elements of indium (In), gallium (Ga), zinc (Zn), tin (Sn), titanium (Ti), and niobium (Nb) without limitation. Specific but non-limiting examples of the oxide may include an indium-tin-zinc oxide (ITZO), an indium-gallium-zinc oxide (IGZO: InGaZnO), a zinc oxide (ZnO), an indium-zinc oxide (IZO), an indium-gallium oxide (IGO), an indium-tin oxide (ITO), and an indium oxide (InO).

The channel region 12A may be a region of the semiconductor layer 12 which is opposed to or in direct opposition to the gate electrode 14. Referring to FIG. 2B, the channel region 12A may be overlapped, in plan view, with the gate electrode 14 (more specifically, overlapped with an electrode layer 14A1 to be described later). A region near an interface between the channel region 12A and the low-resistance region 12B may contain a slight amount of metal element contained in the low-resistance region 12B, to an extent that an influence exerted by the metal element is negligible. The channel region 12A may have a channel length L that is preferably, without limitation, the same as a width d1 of the gate electrode 14 (more specifically, a width of the electrode layer 14A1). For example, the channel region 12A may have a width, i.e., the channel length L, of 3 μm or more without limitation.

The low-resistance region 12B may serve to stabilize characteristics of the thin-film transistor 1, and provided in a region of the semiconductor layer 12 which is non-opposed to the gate electrode 14 as illustrated in FIG. 2B. More specifically, the low-resistance region 12B may be provided in a region of the semiconductor layer 12 which is exposed from the gate electrode 14. The low-resistance region 12B may be formed at a region adjacent to the channel region 12A of the semiconductor layer 12 by means of a self-aligned process to be described later. Note that the low-resistance region 12B is illustrated here as being formed throughout the entire region in a thickness direction of the semiconductor layer 12. However, the low-resistance region 12B may be formed only at a part of a surface of the semiconductor layer 12, e.g., a part of a face of the semiconductor layer 12 which is in contact with the high-resistance film 15.

The low-resistance region 12B may be a region that contains a metal element diffused as a dopant into an oxide semiconductor that forms the semiconductor layer 12. Non-limiting examples of the metal element may include aluminum (Al), indium, titanium, and tin.

The gate insulating film 13 may be a single-layer film such as a silicon oxide film (SiOx), a silicon nitride film (SiNx), a silicon oxynitride film (SiON), and an aluminum oxide film (AlOx), or may be a laminated film of two or more thereof. The gate insulating film 13 may have a thickness in a range from 50 nm to 300 nm in one embodiment where the gate insulating film 13 is a single-layer silicon oxide film. The gate insulating film 13 according to the present example embodiment may have been processed together with a part of the gate electrode 14 (i.e., together with the electrode layer 14A1 to be described later) in a continuous fashion, i.e., by means of single etching. In other words, the gate electrode 14 (i.e., the electrode layer 14A1) and the gate insulating film 13 may have the same shape in plan view.

The gate electrode 14 may serve to control a carrier density in the semiconductor layer 12 by means of application of a gate voltage (Vg), and serve as a wiring line that supplies an electric potential. The gate electrode 14 according to the present example embodiment includes the electrode layer 14A1 and an electrode layer 14A2 in the order from the gate insulating film 13. The electrode layer 14A1 and the electrode layer 14A2 may respectively serve as a first electrode layer and a second electrode layer in one embodiment. In other words, the gate electrode 14 may be a laminated film that includes the electrode layers 14A1 and 14A2.

The electrode layers 14A1 and 14A2 have respective widths (widths d1 and d2 in a direction of the channel length L) that are different from each other. In one specific but non-limiting embodiment, the electrode layer 14A1 has the width d1 that is greater than the width d2 of the electrode layer 14A2.

The electrode layer 14A1 may be a lower layer (disposed on the side that faces the gate insulating film 13) of the gate electrode 14, and may have a shape same as that of the gate insulating film 13 in plan view. The width d1 of the electrode layer 14A1 may be substantially the same as the channel length L, for example. The width d1 may serve as a first width in one embodiment. The term “channel length L” as used herein refers to an ideal channel length where a parasitic capacitance is ignored. The channel length L in practice may vary depending on spread of an electric field upon application of voltage to the gate electrode 14, a gradient (i.e., a channel end low-resistance region to be described later) of carrier density at a channel end (an interface between the channel region 12A and the low-resistance region 12B), or any other factor. The width d1 may preferably be, without limitation, a width of a lower surface S11 out of two surfaces of the electrode layer 14A1, i.e., the lower surface S11 that faces the gate insulating film 13 and an upper surface S12 that faces the electrode layer 14A2. In one embodiment where the electrode layer 14A1 is processed by means of dry etching, side surfaces of the electrode layer 14A1 each may be a substantially vertical surface as described later, meaning that the electrode layer 14A1 may have a rectangular cross-sectional shape. Thus, the lower surface S11 may have a width substantially the same as a width of the upper surface S12. Further, the side surface of the electrode layer 14A1 and a side surface of the gate insulating film 13 may form a single vertical surface, for example.

The electrode layer 14A2 may be opposed to the channel region 12A and disposed on the upper layer of the gate electrode 14. The width d2 of the electrode layer 14A2 may preferably be, without limitation, a width of a lower surface S21 out of two surfaces of the electrode layer 14A2, i.e., the lower surface S21 that faces the electrode layer 14A1 and an upper surface S22. The width d2 may serve as a second width in one embodiment.

The widths d1 and d2 each may be set depending on the channel length L. A difference between the widths d1 and d2 (equivalent to a sum of two “d” denoted in FIG. 2A) may be one μm or less. For example, the difference between the widths d1 and d2 which is greater than one μm (where d>0.5 μm) allows for easier supply of oxygen to the channel region 12A and thus makes it easier to prevent ends of the channel region 12A from being made low in electric resistance. On the other hand, making the difference between the widths d1 and d2 larger (making “d” larger) leads to the smaller width d2. For example, in consideration of the electrode layer 14A2 that also serves as a gate wiring line, decreasing the width d2 down to about 2 μm may result in higher resistance or a reduction in yield attributable to delamination. To secure the difference between the widths d1 and d2, measures may be taken to make the width d1 larger instead of making the width d2 smaller. This, however, increases a size of a transistor and may make it difficult to achieve the reduction in parasitic capacitance accordingly. In general, a wiring line in a thin-film transistor array for display application is formed to have a width of about 4 μm. This means that, for such a wiring line width, it is possible to secure 3 μm or greater for the width d2 when “d” is made equal to or less than 0.5 μm (when the sum of two “d” is equal to or less than 1.0 μm) to prevent the resistance from becoming high and to prevent generation of the delamination. Hence, making the difference between the widths d1 and d2 one μm or less allows for the easier supply of oxygen to the channel region 12A and thus makes it easier to prevent the ends of the channel region 12A from being made low in electric resistance, while preventing the gate electrode 14 from becoming higher in resistance and preventing the reduction in yield.

The electrode layers 14A1 and 14A2 may have respective thicknesses that are different from each other. In one specific but non-limiting embodiment, the electrode layer 14A1 may have a thickness t1 that is smaller (i.e., thinner) than a thickness t2 of the electrode layer 14A2. The thicknesses t1 and t2 each may be set to any appropriate size depending on a factor such as the channel length L and materials forming the electrode layers 14A1 and 14A2. For example, the thickness t1 may be preferably 100 nm or less from the viewpoint of oxygen permeability without limitation. The thickness t2 may be preferably set from the viewpoint of an electric conductivity necessary as the gate electrode or the gate wiring line, without particular limitation.

Materials forming the electrode layers 14A1 and 14A2 may be the same as each other. Preferably, without limitation, the materials forming the electrode layers 14A1 and 14A2 may be different from each other. Using materials different from each other in etching resistance for the respective electrode layers 14A1 and 14A2 makes it easier to secure etching selectivity between the electrode layer 14A2 and the electrode layer 14A1 and between the electrode layer 14A2 and the gate insulating film 13 upon a manufacturing process to be described later, and thereby makes it possible to form the laminated structure as described above with accuracy. The electrode layers 14A1 and 14A2 each may be made of, for example, a simple substance of one of titanium (Ti), tungsten (W), tantalum (Ta), aluminum (Al), molybdenum (Mo), silver (Ag), neodymium (Nd), and copper (Cu), or an alloy of any combination thereof. In an alternative embodiment, the electrode layers 14A1 and 14A2 each may be a compound film that contains one or more of the foregoing elements, or a laminated film that contains two or more of the foregoing elements. The electrode layers 14A1 and 14A2 each may be a transparent conductive film such as an indium-tin oxide (ITO) film. Non-limiting examples of the material suitable for the electrode layer 14A1 may include a titanium alloy, titanium nitride (TiN), tungsten, a tungsten alloy, tantalum, tantalum nitride (TaN), and any combination thereof. Non-limiting examples of the material suitable for the electrode layer 14A2 may include aluminum, molybdenum, copper, an aluminum alloy, a copper alloy, and any combination thereof.

The high-resistance film 15 may be provided in contact with the low-resistance region 12B of the semiconductor layer 12. The high-resistance film 15 may be a remainder, as an oxidized film, of a metal film that has served as a supply source of the metal element diffused into the low-resistance region 12B following the manufacturing process to be described later. The high-resistance film 15 may be made of an oxide such as a titanium oxide, an aluminum oxide, an indium oxide, and a tin oxide. The high-resistance film 15 may be removed after the formation of the low-resistance region 12B. In an alternative embodiment, the high-resistance film 15 may remain after the formation of the low-resistance region 12B from the viewpoint of the foregoing metal-oxidized film that serves also as a moisture barrier film.

The interlayer insulating film 16 may be made of an organic material such as an acrylic-based resin, polyimide, and a novolac-based resin. In an alternative embodiment, the interlayer insulating film 16 may be made of an inorganic material such as a silicon oxide, a silicon nitride, a silicon oxynitride, and an aluminum oxide.

The source-drain electrode 17 may serve as a source or a drain of the thin-film transistor 1. The source-drain electrode 17 may be made of a metal or a transparent conductive film similar to any of the foregoing materials given as examples of the material that forms the gate electrode 14. It is preferable, without limitation, that a material having a good electric conductivity be selected for the source-drain electrode 17.

### [Manufacturing Method]

The foregoing thin-film transistor 1 may be manufactured in the following example manner. FIGS. 3 to 8 illustrate, in the process step order, a manufacturing process of the thin-film transistor 1.

Referring to FIG. 3, the semiconductor layer 12 may be formed on the substrate 11 first. The semiconductor layer 12 may be made of any material described above, such as IGZO. In one specific but non-limiting embodiment, an oxide semiconductor film may be formed over an entire surface of the substrate 11 first, using a method such as sputtering, electron beam evaporation, pulsed laser deposition (PLD), ion plating, and a sol-gel processing. The thus-formed oxide semiconductor film may be patterned into a predetermined shape using a method such as photolithography and etching.

Referring to FIG. 4, the gate insulating film 13 may be thereafter formed over an entire surface of the substrate 11 using a method such as chemical vapor deposition (CVD), sputtering, electron beam evaporation, and atomic layer deposition (ALD). The gate insulating film 13 may be made of any material described above. Thereafter, the electrode layers 14A1 and 14A2 may be formed in order on the thus-formed gate insulating film 13 using a method such as sputtering, thermal deposition, and electron beam evaporation. The electrode layers 14A1 and 14A2 each may be made of any material and have the thickness as described above. Upon the formation of the electrode layers 14A1 and 14A2, it is preferable, without limitation, that the materials different from each other in etching resistance be selected for the respective electrode layers 14A1 and 14A2 as described above. For example, a material processable by wet etching may be selected for the electrode layer 14A2. The use of wet etching allows etching to progress isotropically and makes it easier for an end processed by the isotropic etching to be shifted inward relative to a resist end. For the electrode layer 14A1, a material having resistance to a wet etching liquid used upon the etching of the electrode layer 14A2 and processable by dry etching may be selected. The use of dry etching allows etching to progress anisotropically and makes it easier to bring an end processed by the anisotropic etching into coincidence with a region near the resist end. In one embodiment, a titanium film and a laminated film that includes an aluminum film and a molybdenum film may be respectively used for the electrode layer 14A1 and the electrode layer 14A2.

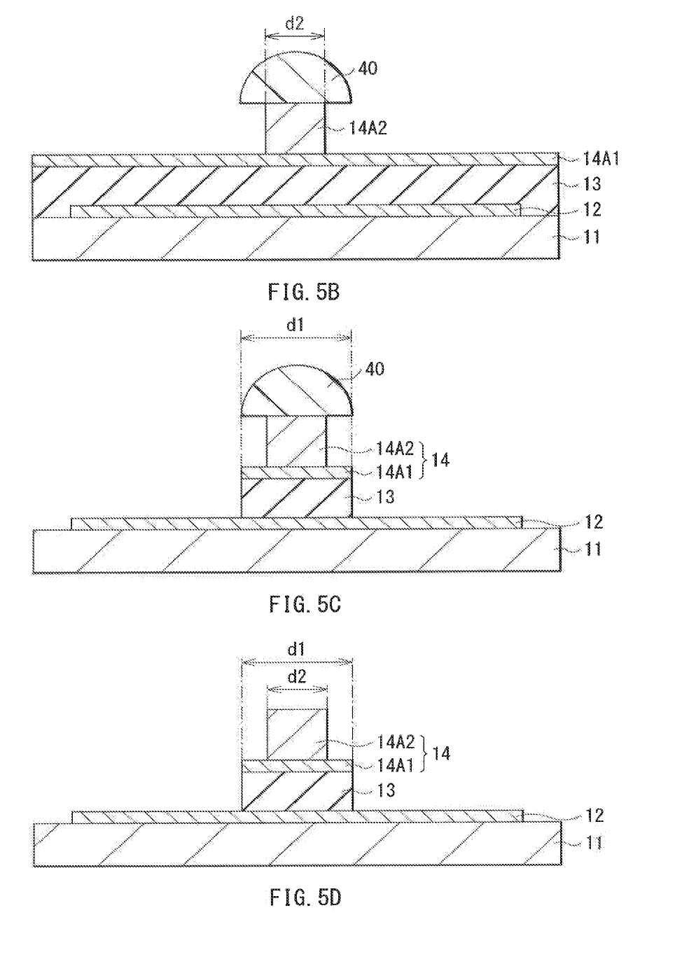

Referring to FIG. 5A, a photoresist film 40 may be thereafter patterned in a selective region on the electrode layer 14A2 using a method such as photolithography. For example, the photoresist film 40 may have a width equivalent to the width d1 of the electrode layer 14A1.

Referring to FIG. 5B, the electrode layer 14A2 may be thereafter processed using a method such as wet etching. The use of wet etching allows etching to progress in the electrode layer 14A1 both in a thickness direction (a vertical direction) of the electrode layer 14A1 and in a lateral direction of the electrode layer 14A1 (i.e., causes side etching). Thus, the photoresist film 40 may so remain as to cover the electrode layer 14A1 in the form of eaves. So controlling a width of the lateral etching that the lateral etching width is set to an appropriate size makes it possible to control the width d2 of the electrode layer 14A1.

Referring to FIG. 5C, the electrode layer 14A1 and the gate insulating film 13 may be thereafter processed collectively using a method such as dry etching. The use of dry etching allows etching to progress in the electrode layer 14A1 and the gate insulating film 13 in a thickness direction (in a vertical direction) thereof, causing the width d1 of the electrode layer 14A1 to be set to a size that is equivalent to the width of the photoresist film 40. Further, the collective processing by means of the dry etching allows the electrode layer 14A1 and the gate insulating film 13 to have the same shape as each other in plan view and allows the side surfaces of each of the electrode layer 14A1 and the gate insulating film 13 to be the vertical surfaces.

Moreover, selecting the material that secures the etching selectivity for each of the electrode layers 14A1 and 14A2 as described above allows for the collective processing of the electrode layer 14A1 and the gate insulating film 13 (by means of the dry etching without limitation) after the electrode layer 14A2 is processed (by means of the wet etching without limitation). This makes it difficult to cause a process error in shape and size of the electrode layer 14A1, i.e., makes it easier to control the channel length in the channel region 12A.

Referring to FIG. 5D, the photoresist film 40 may be thereafter removed to form the gate electrode 14 having the laminated film that includes the electrode layers 14A1 and 14A2.

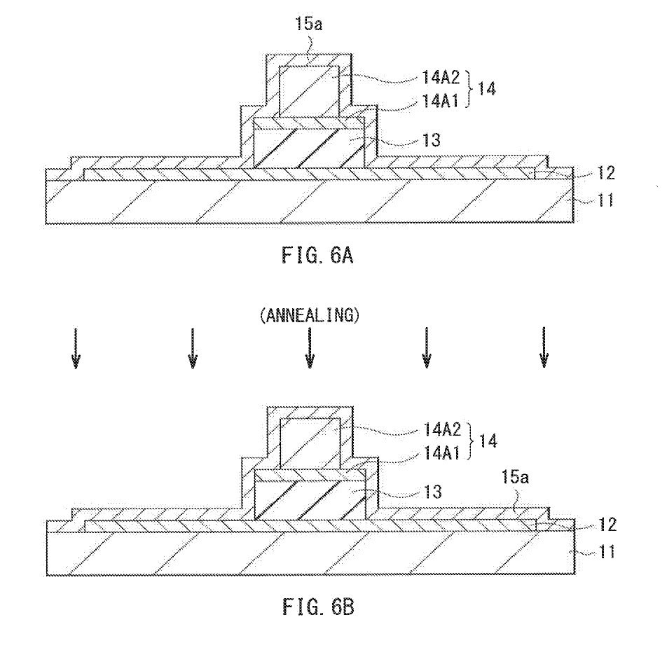

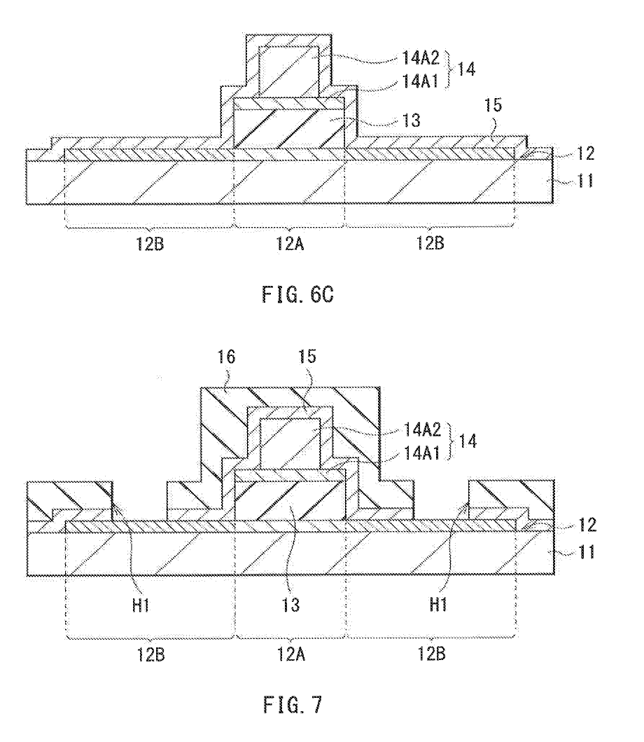

Thereafter, the low-resistance region 12B may be formed on the semiconductor layer 12 using the self-aligned process. In one specific but non-limiting embodiment, a thin metal film 15a may be first formed over an entire surface of the substrate 11 using a method such as sputtering and atomic layer deposition, as illustrated in FIG. 6A. The metal film 15a may be made of any metal element described above, such as aluminum.

Referring to FIG. 6B, annealing may be thereafter performed at a predetermined temperature and under a predetermined atmosphere such as an oxygen atmosphere. This results in abstraction of oxygen that migrates to the metal film 15a in a region of the semiconductor layer 12 which is in contact with the metal film 15a, whereas a diffusion of the metal element occurs from the metal film 15a.

As a result, the metal film 15a may be oxidized and may remain as the high-resistance film 15 as illustrated in FIG. 6C (i.e., the high-resistance film 15 may be formed). Further, the region of the semiconductor layer 12 which is in contact with the high-resistance film 15 (i.e., the region non-opposed to the electrode layer 14A1) may serve as the low-resistance region 12B that has the electric resistance lower than the channel region 12A, owing to an increase in the carrier density caused by an increase in oxygen defect in the semiconductor layer 12 and owing to the diffused metal element that serves as a dopant. It is to be noted that the annealing may be performed multiple times thereafter until the thin-film transistor 1 is completed.

Referring to FIG. 7, the interlayer insulating film 16 may be thereafter formed over an entire surface of the high-resistance film 15. The interlayer insulating film 16 may be formed using a method such as coating in one embodiment where the interlayer insulating film 16 is made of an organic material. In one embodiment where the interlayer insulating film 16 is made of an inorganic material, the interlayer insulating film 16 may be formed using a method such as chemical vapor deposition, sputtering, and atomic layer deposition. Thereafter, the contact hole H1 may be formed on the region of the semiconductor layer 12 which faces the low-resistance region 12B using a method such as lithography.

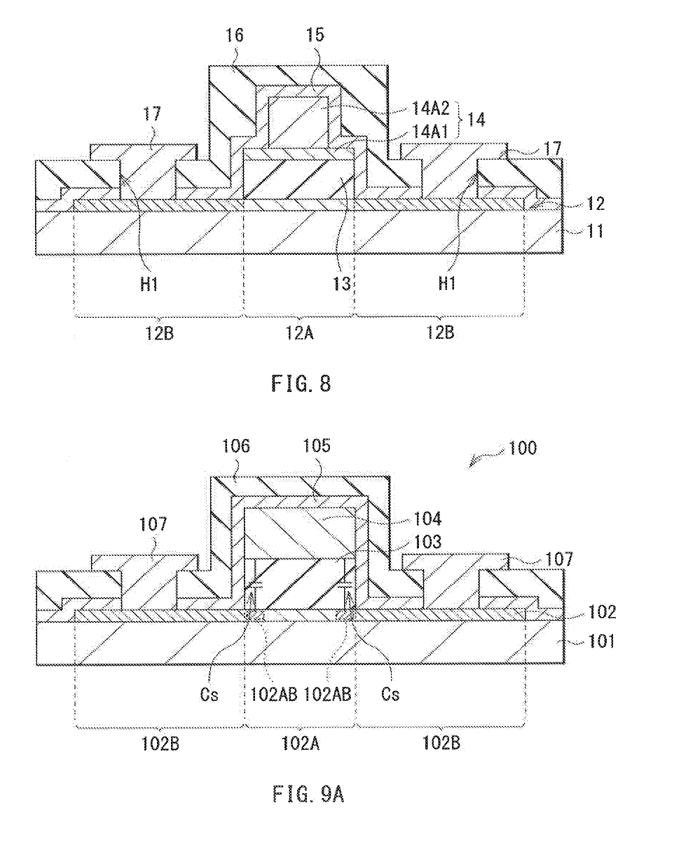

Referring to FIG. 8, the source-drain electrode 17 may be thereafter formed. In one specific but non-limiting embodiment, a film made of any metal material described above may be so formed on the interlayer insulating film 16 that the contact hole H1 is filled with the metal material film, following which the metal material film may be patterned using a method such as photolithography and etching. Thus, the source-drain electrode 17 may be electrically coupled to the low-resistance region 12B of the semiconductor layer 12. This may complete the thin-film transistor 1 illustrated in FIG. 1.

### [Function and Effect]

The thin-film transistor 1 according to the present example embodiment may involve activation of the channel region 12A of the semiconductor layer 12 upon application, to the gate electrode 14, of an on-voltage that is equal to or greater than a threshold voltage. Thus, a current may flow between the pair of source-drain electrodes 17 through the low-resistance region 12B.

It is to be noted that the parasitic capacitance may be generated between the channel region 12A of the semiconductor layer 12 and the gate electrode 14, in the thin-film transistor 1 in which the semiconductor layer 12 includes the low-resistance region 12B. Any embodiment of the disclosure, however, makes it possible to suppress the generation of the parasitic capacitance, for one reason described below.

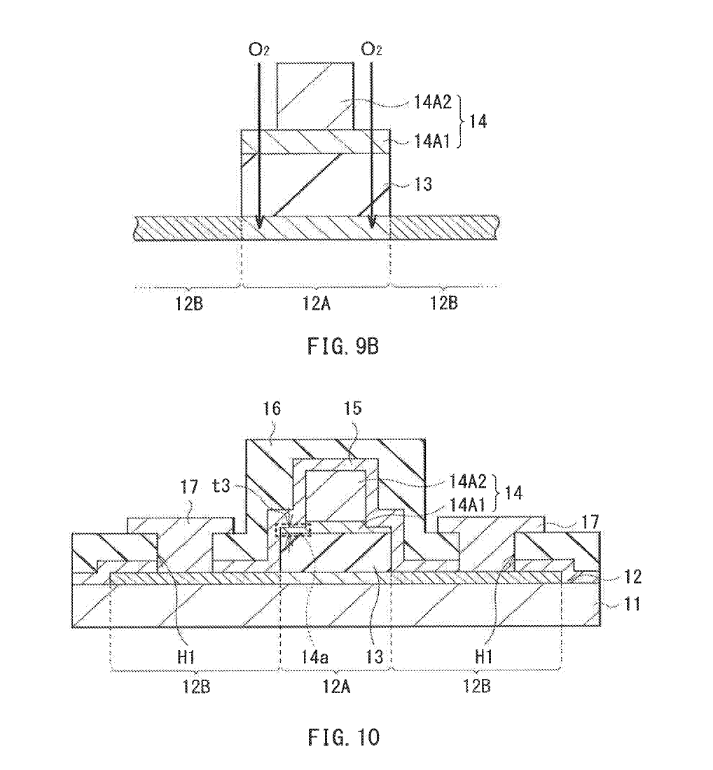

FIG. 9A illustrates a cross-sectional configuration of a thin-film transistor (a thin-film transistor 100) according to a comparative example. As with the thin-film transistor 1 according to the present example embodiment, the thin-film transistor 100 is a top-gate thin-film transistor having a self-aligned structure. The thin-film transistor 100 has a semiconductor layer 102 (an oxide semiconductor layer) in a selective region on a substrate 101. The semiconductor layer 102 includes a channel region 102A and a low-resistance region 102B. The thin-film transistor 100 also has a gate insulating film 103 and a gate electrode 104 provided in this order on the semiconductor layer 102, and a high-resistance film 105 and an interlayer insulating film 106 so provided as to cover the semiconductor layer 102, the gate insulating film 103, and the gate electrode 104. The thin-film transistor 100 may have a source-drain electrode 107 provided on the interlayer insulating film 106 and electrically coupled to the low-resistance region 102B of the semiconductor layer 102. In the thin-film transistor 100, the low-resistance region 102B of the semiconductor layer 102 is also formed by a self-aligned process, as with the low-resistance region 12B of the semiconductor layer 12 according to the present example embodiment. Further, the annealing may be performed multiple times following the self-aligned process until the thin-film transistor 100 is completed.

The thin-film transistor 100 differs from the thin-film transistor 1 according to the present example embodiment in that the gate electrode 104 is a single-layer film, or a laminated film in which widths in the channel length of respective layers are the same as each other.

The thin-film transistor 100 according to the comparative example involves difficulties in supplying oxygen to ends of the channel region 102A upon the annealing, due to the presence of the gate electrode 104 provided above the channel region 102A and having a substantially even thickness. This results in easier generation of a region in which the electric resistance is low in the channel region 102A of the semiconductor layer 102, especially at the ends of the channel region 102A (i.e., the channel end low-resistance region 102AB), owing to the oxygen abstraction. In other words, a parasitic capacitance Cs is generated between the region (especially the channel end low-resistance region 102AB) and the opposing gate electrode 104. The generation of the parasitic capacitance Cs influences a driving speed. Further, the thin-film transistor 100 according to the comparative example involves a large step between the semiconductor layer 102 and the gate electrode 104 easily. This results in unfavorable step coverage by a film to be formed on or above the gate electrode 104, such as the inorganic interlayer insulating layer 106.

Moreover, a width of the channel end low-resistance region 102AB (i.e., a channel shrink length) may sometimes increase to about one μm or even greater depending on annealing conditions. For example, an excessive increase in the width of the channel end low-resistance region 102AB when the channel length is about 4 μm may largely shift a threshold voltage (i.e., a Vth voltage) of the thin-film transistor 100, e.g., may shift the threshold voltage to the negative side when the thin-film transistor 100 is a n-type semiconductor. In this case, the thin-film transistor 100 fails to function as a switching device.

In contrast, the thin-film transistor 1 according to the present example embodiment has the gate electrode 14 that includes the electrode layers 14A1 and 14A2 in the order from the gate insulating film 13, i.e., the gate electrode 14 is the laminated film. Further, the electrode layer 14A1 has the width d1 that is greater than the width d2 of the electrode layer 14A2. Thus, oxygen is easily supplied to the ends of the channel region 12A of the semiconductor layer 12 upon, for example, the annealing as illustrated in FIG. 9B, making it possible to prevent the ends of the channel region 12A from being made low in resistance, i.e., making it possible to reduce a region equivalent to the foregoing channel end low-resistance region 102AB. Hence, it is possible to reduce the generation of the parasitic capacitance between the ends of the channel region 12A and the gate electrode 14, and thereby to allow for a high-speed operation. Further, the thin-film transistor 1 according to the present example embodiment allows the gate electrode 14 to have the stepwise ends, making it possible to improve the step coverage as compared with the comparative example.

In the present example embodiment, the thickness t1 of the electrode layer 14A1 may be less than the thickness t2 of the electrode layer 14A2 in the gate electrode 14. Hence, it is possible to supply oxygen to the ends of the channel region 12A more effectively. In one specific but non-limiting embodiment, the thickness t1 of the electrode layer 14A1 may be 100 nm or less.

In the present example embodiment, the electrode layers 14A1 and 14A2 may be made of the materials different from each other. In one specific but non-limiting embodiment, the material that allows for securing of the etching selectivity may be selected for each of the electrode layers 14A1 and 14A2. This makes it possible to form the laminated structure that includes the electrode layers 14A1 and 14A2 with favorable accuracy. It is to be noted that, in the self-aligned structure as employed in the present example embodiment, finished dimensions of the gate electrode 14 largely influence the channel length. Hence, increasing a processing accuracy of the gate electrode (especially the electrode layer 14A1) makes it easier to control the channel length, which in turn leads to an increase in characteristics and reliability of the thin-film transistor 1 and makes it possible to address higher definition.

According to the foregoing example embodiment, the gate electrode 14 includes the electrode layers 14A1 and 14A2 in the order from the gate insulating film 13, i.e., the gate electrode 14 is the laminated film, and the electrode layer 14A1 has the width d1 that is greater than the width d2 of the electrode layer 14A2. Thus, oxygen is easily supplied to the ends of the channel region 12A of the semiconductor layer 12, making it possible to prevent the ends of the channel region 12A from being made low in resistance (i.e., reduce the channel end low-resistance region 102AB), and thereby to suppress the generation of the parasitic capacitance. Hence, it is possible to reduce the parasitic capacitance in the thin-film transistor 1.

In the following, a description is given of some modification examples of the present example embodiment. Note that the same or equivalent elements as those of the example embodiment described above are denoted with the same reference numerals, and will not be described in detail.

### Modification Example 1

FIG. 10 illustrates a cross-sectional configuration of a thin-film transistor according to modification example 1. As with the thin-film transistor 1 according to the example embodiment as described, the thin-film transistor according to the modification example 1 may be a top-gate thin-film transistor having a self-aligned structure. The thin-film transistor has the semiconductor layer 12 in a selective region on the substrate 11. The semiconductor layer 12 includes the channel region 12A and the low-resistance region 12B. The thin-film transistor also has the gate insulating film 13 and the gate electrode 14 provided in this order on the semiconductor layer 12, and may have the high-resistance film 15 and the interlayer insulating film 16 so provided as to cover the semiconductor layer 12, the gate insulating film 13, and the gate electrode 14. The thin-film transistor has the source-drain electrode 17 provided on the interlayer insulating film 16 and electrically coupled to the low-resistance region 12B of the semi conductor layer 12.

The modification example 1 differs from the foregoing example embodiment in that the electrode layer 14A1 of the gate electrode 14 includes a thin-film region 14a. The thin-film region 14a may be a region non-opposed to the electrode layer 14A2, i.e., a region exposed from the electrode layer 14A2. The thin-film region 14a may have a thickness t3 that is less than a region of the electrode layer 14A1 which is opposed to or overlapped with the electrode layer 14A2. For example, the thickness t3 of the thin-film region 14a may be within a range from 5 nm to 30 nm.

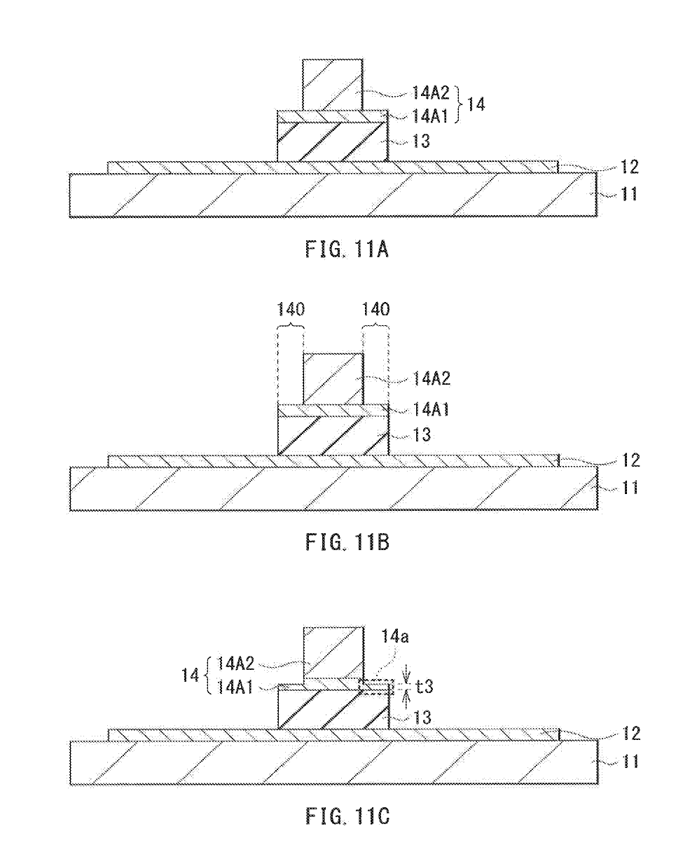

FIGS. 11A to 11C are each a cross-sectional view of a process in a method of manufacturing the thin-film transistor according to the modification example 1. The gate electrode 14 of the thin-film transistor according to the modification example 1 may be manufactured in the following example manner. Referring to FIG. 11A, processes similar to those described in the foregoing example embodiment may be first carried out to so perform patterning as to form the gate insulating film 13, the electrode layer 14A1, and the electrode layer 14A2 on the semiconductor layer 12. In one specific but non-limiting embodiment, the gate insulating film 13 and the electrode layers 14A1 and 14A2 may be formed on the semiconductor layer 12, followed by the processing of the electrode layer 14A2 and the collective processing of the gate insulating film 13 and the electrode layer 14A1 thereafter.

Thereafter, referring to FIG. 11B, etching such as dry etching may be performed again in the modification example 1 using the electrode layer 14A2 as a mask. The dry etching causes a thickness of a region 140 of the electrode layer 14A1 exposed from the electrode layer 14A2 to be thin. The dry etching may be stopped when the region 140 is made thin. An etching condition may be controlled in this way to allow for the even thinner electrode layer 14A1, i.e., allow for formation of the thin-film region 14a.

As exemplified in the modification example 1, the electrode layer 14A1 of the gate electrode 14 may include the thin-film region 14a provided in a region non-opposed to the electrode layer 14A2 and having the thickness less than the thickness of the region opposed to the electrode layer 14A2. Hence, it is possible to supply oxygen to the ends of the channel region 12A of the semiconductor layer 12 more easily and prevent the ends of the channel region 12A of the semiconductor layer 12 from being made low in electric resistance more easily. It is also possible for the modification example 1 to achieve effects equivalent to those achieved by the example embodiment as described.

### Modification Example 2

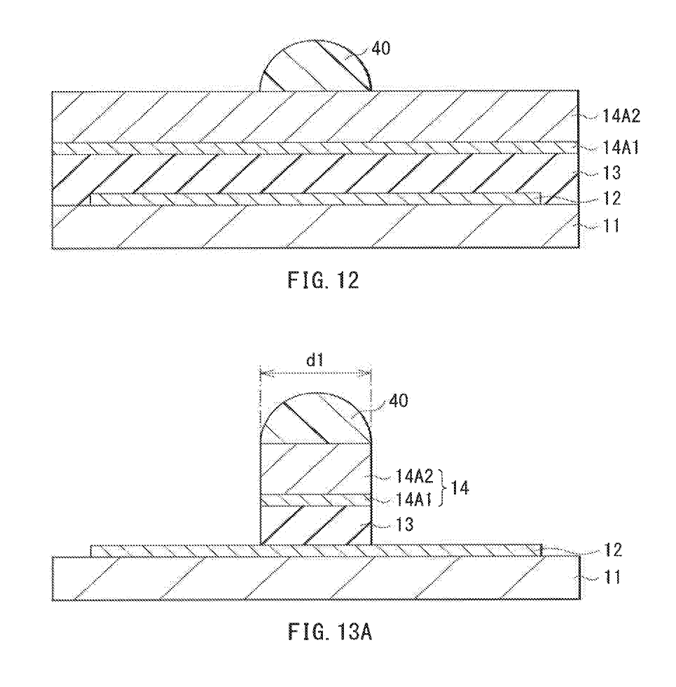

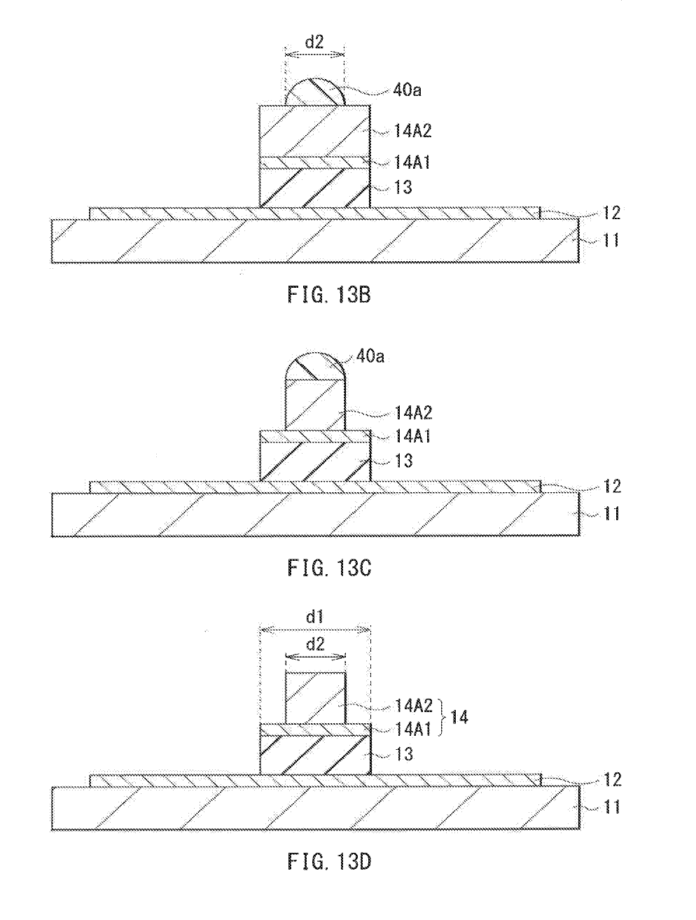

FIGS. 12 to 13D are each a cross-sectional view for describing a method of forming the gate electrode 14 according to modification example 2. Upon the formation of the gate electrode 14 in the foregoing example embodiment, the electrode layer 14A2 may be processed first among the gate insulating film 13 and the electrode layers 14A1 and 14A2 which are formed on the semiconductor layer 12, following which the electrode layer 14A1 and the gate insulating film 13 may be collectively processed. A method of forming the gate electrode according to embodiments of the disclosure, however, is not limited to that described above. Alternatively, the gate electrode may be formed as exemplified by the modification example 2 described below.

Referring to FIG. 12, processes similar to those described in the foregoing example embodiment may be performed to form the gate insulating film 13, the electrode layer 14A1, and the electrode layer 14A2 in this order on the semiconductor layer 12 and to form the photoresist film 40 in a selective region on the electrode layer 14A2. Note that materials similar to those exemplified in the foregoing example embodiment may be used as materials forming the electrode layers 14A1 and 14A2 according to the modification example 2. The materials forming the electrode layers 14A1 and 14A2 may be the same as each other. Alternatively, the materials forming the electrode layers 14A1 and 14A2 may be different from each other. Any material appropriate to etching conditions may be selected for each of the electrode layers 14A1 and 14A2.

Referring to FIG. 13A, etching such as dry etching may be thereafter performed on the electrode layer 14A2, the electrode layer 14A1, and the gate insulating film 13 in the modification example 2 using the photoresist film 40 as a mask. As a result, the electrode layer 14A2, the electrode layer 14A1, and the gate insulating film 13 may be so patterned as to have respective sizes equivalent to the width of the photoresist film 40. The width of the photoresist film 40 may be equivalent to the width d1.

Referring to FIG. 13B, a photoresist film 40a having a width narrower than the width of the photoresist film 40 may be thereafter formed using a method such as ashing. The width of the photoresist film 40a may be equivalent to the width d2. The ashing may involve the use of oxygen gas or any other suitable gas.

Referring to FIG. 13C, etching such as dry etching may be thereafter performed to selectively etch only the electrode layer 14A1 using the photoresist film 40a as a mask.

Referring to FIG. 13D, the photoresist film 40a may be thereafter removed to complete the formation of the gate electrode 14 in which the electrode layer 14A2 having the width d2 is laminated on the electrode layer 14A1 having the width d1.

As exemplified in the modification example 2, the electrode layer 14A2 may be so processed as to have the width d2 after the electrode layer 14A1 and the gate insulating film 13 are so processed as to have the width d1, upon the formation of the gate electrode 14. The modification example 2, on the other hand, involves exposure of the electrode layer 14A1, formed to have the width d1, to the etching process of the electrode layer 14A2 as illustrated in FIG. 13C. In contrast, the example embodiment as described involves the collective processing of the electrode layer 14A1 and the gate insulating film 13 after the electrode layer 14A2 is processed, preventing the electrode layer 14A1 formed to have the width d1 from being exposed to an etching process unnecessarily. The foregoing example embodiment may be thus advantageous as compared with the modification example 2, in that it is possible to process the gate electrode 14, especially the electrode layer 14A1, with high accuracy and to control the channel length easily.

### Modification Examples 3-1 to 3-3

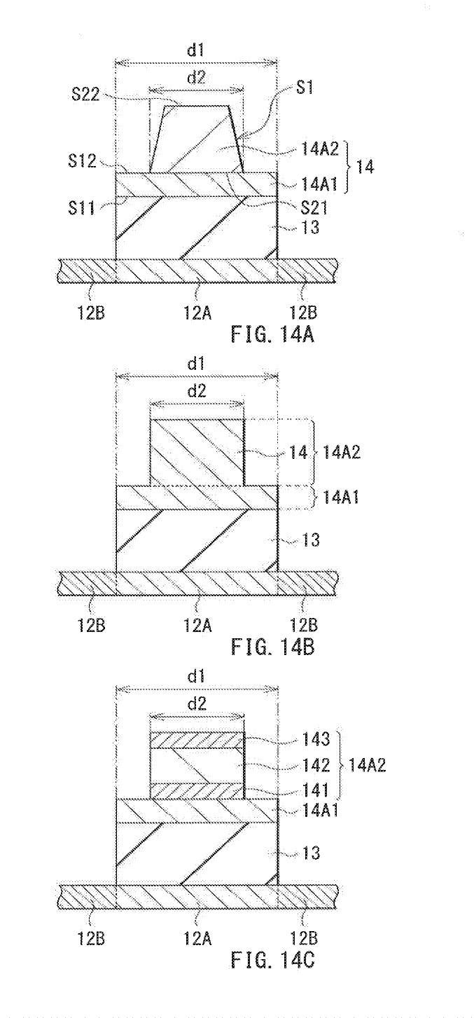

FIG. 14A illustrates a cross-sectional configuration of a key part of a thin-film transistor according to modification example 3-1. FIG. 14B illustrates a cross-sectional configuration of a key part of a thin-film transistor according to modification example 3-2. FIG. 14C illustrates a cross-sectional configuration of a key part of a thin-film transistor according to modification example 3-3. The key part may include the semiconductor layer 12, the gate insulating film 13, and the gate electrode.

The gate electrode 14 according to the example embodiment as described may be the laminated film that includes the electrode layers 14A1 and 14A2. A configuration of each of the electrode layers 14A1 and 14A2, however, may take various forms besides those described above.

Referring to FIG. 14A, the electrode layer 14A2 may have a tapered surface (or an inclined surface) S1 as exemplified by the modification example 3-1. In other words, the electrode layer 14A2 may have a trapezoidal cross-sectional shape. In the modification example 3-1, an upper surface S12 of the electrode layer 14A1 may have the width d1 that is greater than the width d2 of a lower surface S21 of the electrode layer 14A2.

Referring to FIG. 14B, the gate electrode 14 may be a single-layer film, i.e., may be a film made of the same material, instead of the laminated film as exemplified by the modification example 3-2. In the modification example 3-2, the width d1 of the electrode layer 14A1 may be greater than the width d2 of the electrode layer 14A2, where a lower part of the gate electrode 14 is defined as the electrode layer 14A1 and an upper part of the gate electrode 14 is defined as the electrode layer 14A2. In other words, the gate electrode 14 may have a shape in which ends of the gate electrode 14 are thinner than a middle part of the gate electrode 14. For example, the gate electrode 14 may have a stepwise shape or a sloped shape.

Referring to FIG. 14C, the electrode layers 14A1 and 14A2 each may be a single-layer film or a laminated film as exemplified by the modification example 3-3. FIG. 14C illustrates one example in which the electrode layer 14A1 has a single layer, whereas the electrode layer 14A2 has three layers. As can be appreciated from the modification example 3-3, the number of layers included in the gate electrode 14 is not particularly limited as long as the gate electrode 14 includes the electrode layer having the width d1 and the electrode layer having the width d2.

The foregoing modification examples 3-1 to 3-3 each involve the electrode layer 14A1 having the width d1 that is greater than the width d2 of the electrode layer 14A2, making it possible to supply oxygen to the channel region 12A of the semiconductor layer 12 easily. Hence, it is possible for the modification examples 3-1 to 3-3 to achieve effects equivalent to those achieved by the example embodiment as described.

### First Application Example

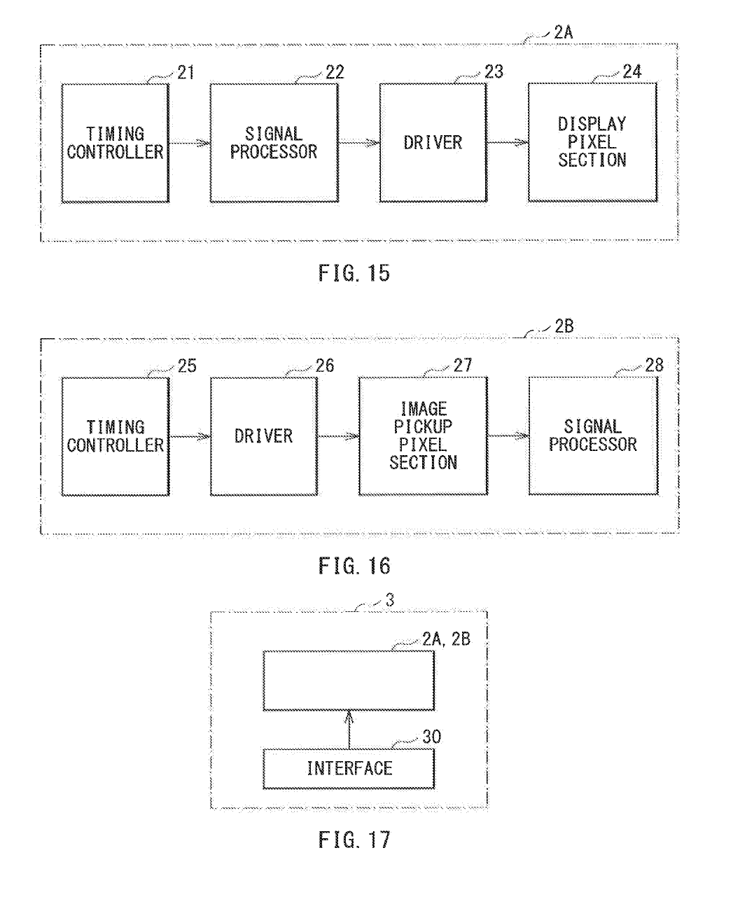

The thin-film transistors (such as the thin-film transistor 1) described in the example embodiment and the modification examples each may be applied to a drive circuit provided in any of various semiconductor units. Non-limiting examples of the semiconductor unit may include a display unit 2A and an image pickup unit 2B. FIG. 15 is a functional block diagram illustrating a configuration of the display unit 2A. FIG. 16 is a functional block diagram illustrating a configuration of the image pickup unit 2B.

The display unit 2A may display, as an image, a picture signal received from the outside of the display unit 2A or generated inside of the display unit 2A. The display unit 2A may be an active-matrix-driven display such as an organic electroluminescence (EL) display and a liquid crystal display (LCD). The display unit 2A may include a timing controller 21, a signal processor 22, a driver 23, and a display pixel section 24.

The timing controller 21 may include a timing generator that generates various timing signals, i.e., control signals. The timing controller 21 may control driving of the signal processor 22, etc., on the basis of the various timing signals. The signal processor 22 may perform a predetermined correction on, for example, the digital picture signal supplied from the outside, and output the thus-obtained picture signal to the driver 23. The driver 23 may include a scanning line driving circuit, a signal line driving circuit, and any other circuit. The driver 23 may drive each pixel provided in the display pixel section 24 through various control lines. The display pixel section 24 may include a display device and a pixel circuit designed to drive the display device on a pixel basis. The display device may be an organic EL device, a liquid crystal display device, or any other device directed to image display. Any of the thin-film transistors according to the example embodiment and the modification examples, such as the thin-film transistor 1 described above, may be used for various circuits provided in the driver 23, the display pixel section 24, or both.

The image pickup unit 2B may be a solid-state image pickup unit that obtains an image as an electric signal, for example. The image pickup unit 2B may include a charge coupled device (CCD) image sensor, a complementary metal oxide semiconductor (CMOS) image sensor, or any other suitable image sensor. The image pickup unit 2B may include a timing controller 25, a driver 26, an image pickup pixel section 27, and a signal processor 28.

The timing controller 25 may include a timing generator that generates various timing signals, i.e., control signals. The timing controller 25 may control driving of the driver 26, on the basis of the various timing signals. The driver 26 may include a row selection circuit, an analog to digital (AD) conversion circuit, and a horizontal transfer scanning circuit. The driver 26 may perform driving that reads out signals from respective pixels provided in the image pickup pixel section 27 through various control lines. The image pickup pixel section 27 may include an image pickup device, i.e., a photoelectric conversion device, and a pixel circuit designed to read out the signals. The image pickup device may be a photodiode or any other device directed to image pickup. The signal processor 28 may apply various signal process operations to the signals obtained from the image pickup pixel section 27. Any of the thin-film transistors according to the example embodiment and the modification examples, such as the thin-film transistor 1 described above, may be used for various circuits provided in the driver 26, the image pickup pixel section 27, or both.

### Second Application Example

The thin-film transistors (such as the thin-film transistor 1) described in the example embodiment and the modification examples, and the semiconductor units such as the display unit 2A and the image pickup unit 2B described in the application examples, each may be applied to any of various electronic apparatuses. FIG. 17 is a functional block diagram illustrating a configuration of an electronic apparatus 3. Non-limiting examples of the electronic apparatus 3 may include a television, a personal computer (PC), a smartphone, a tablet PC, a mobile phone, a digital still camera, a digital video camera, and any other suitable device that includes a thin-film transistor.

The electronic apparatus 3 may include an interface 30 and a semiconductor unit such as the display unit 2A and the image pickup unit 2B described above. The interface 30 may be an input section that receives various signals, a power supply, etc., from the outside. The interface 30 may include a user interface such as a touch panel, a keyboard, and operation buttons.

Although the technology has been described by way of example with reference to the example embodiments, the modification examples, and the application examples, the technology is not limited thereto but may be modified in a wide variety of ways. Factors such as material and thickness of each layer exemplified in the foregoing example embodiments and the modification examples are illustrative and non-limiting. Any other material, any other thickness, and any other factor may be adopted besides those described above. It is not essential for the foregoing thin-film transistors to include all of the layers described above. The foregoing thin-film transistors may further include any other layer in addition to the layers described above. Further, effects described in the example embodiments and the modifications are illustrative and non-limiting. Effects achieved by the technology may be those that are different from the above-described effects, or may include other effects in addition to those described above.

Furthermore, the technology encompasses any possible combination of some or all of the various embodiments described herein and incorporated herein.

It is possible to achieve at least the following configurations from the above-described example embodiments of the disclosure.

(1) A thin-film transistor, including:

an oxide semiconductor layer including a channel region and a low-resistance region that has an electric resistance lower than an electric resistance of the channel region;

a gate insulating film provided on the oxide semiconductor layer;

a gate electrode provided on the gate insulating film and opposed to the channel region of the oxide semiconductor layer, the gate electrode including a first electrode layer and a second electrode layer in order from the gate insulating film, the first electrode layer having a first width that is along a channel length and greater than a second width of the second electrode layer along the channel length; and

a source-drain electrode electrically coupled to the low-resistance region of the oxide semiconductor layer.

(2) The thin-film transistor according to (1), wherein the first electrode layer has a thickness that is less than a thickness of the second electrode layer.
(3) The thin-film transistor according to (1) or (2), wherein the first electrode layer includes:

an opposed region opposed to the second electrode layer; and

a non-opposed region non-opposed to the second electrode layer and having a thickness that is less than a thickness of the opposed region.

(4) The thin-film transistor according to any one of (1) to (3), wherein

the first electrode layer includes a surface opposed to the gate insulating film and having the first width, and

the second electrode layer includes a surface opposed to the first electrode layer and having the second width.

(5) The thin-film transistor according to any one of (1) to (4), wherein a difference between the first width and the second width is one μm or less.
(6) The thin-film transistor according to any one of (1) to (5), wherein the first electrode layer has a thickness that is 100 nm or less.
(7) The thin-film transistor according to any one of (1) to (6), wherein the first electrode layer and the second electrode layer are made of materials different from each other.
(8) The thin-film transistor according to (7), wherein the first electrode layer includes one or more selected from the group consisting of a titanium alloy, titanium nitride, tungsten, a tungsten alloy, tantalum, and tantalum nitride.
(9) The thin-film transistor according to (7), wherein the second electrode layer includes one or more selected from the group consisting of aluminum, molybdenum, copper, an aluminum alloy, and a copper alloy.
(10) The thin-film transistor according to any one of (1) to (9), wherein the gate insulating film and the first electrode layer have a same shape in plan view.
(11) The thin-film transistor according to (10), wherein the gate insulating film and the first electrode layer have side surfaces that form a vertical surface.
(12) The thin-film transistor according to any one of (1) to (11), further including a high-resistance film that is in contact with the low-resistance region.
(13) A semiconductor unit with a drive circuit, the drive circuit being provided with a thin-film transistor, the thin-film transistor including:

an oxide semiconductor layer including a channel region and a low-resistance region that has an electric resistance lower than an electric resistance of the channel region;

a gate insulating film provided on the oxide semiconductor layer;

a gate electrode provided on the gate insulating film and opposed to the channel region of the oxide semiconductor layer, the gate electrode including a first electrode layer and a second electrode layer in order from the gate insulating film, the first electrode layer having a first width that is along a channel length and greater than a second width of the second electrode layer along the channel length; and

a source-drain electrode electrically coupled to the low-resistance region of the oxide semiconductor layer.

(14) The semiconductor unit according to (13), further including a display device driven by the drive circuit.
(15) The semiconductor unit according to (13), further including an image pickup device driven by the drive circuit.
(16) An electronic apparatus with a drive circuit, the drive circuit being provided with a thin-film transistor, the thin-film transistor including:

an oxide semiconductor layer including a channel region and a low-resistance region that has an electric resistance lower than an electric resistance of the channel region;

a gate insulating film provided on the oxide semiconductor layer;

a gate electrode provided on the gate insulating film and opposed to the channel region of the oxide semiconductor layer, the gate electrode including a first electrode layer and a second electrode layer in order from the gate insulating film, the first electrode layer having a first width that is along a channel length and greater than a second width of the second electrode layer along the channel length; and

a source-drain electrode electrically coupled to the low-resistance region of the oxide semiconductor layer.

Although the technology has been described in terms of exemplary embodiments, it is not limited thereto. It should be appreciated that variations may be made in the described embodiments by persons skilled in the art without departing from the scope of the technology as defined by the following claims. The limitations in the claims are to be interpreted broadly based on the language employed in the claims and not limited to examples described in this specification or during the prosecution of the application, and the examples are to be construed as non-exclusive. For example, in this disclosure, the term “preferably”, “preferred” or the like is non-exclusive and means “preferably”, but not limited to. The use of the terms first, second, etc. do not denote any order or importance, but rather the terms first, second, etc. are used to distinguish one element from another. The term “substantially” and its variations are defined as being largely but not necessarily wholly what is specified as understood by one of ordinary skill in the art. The term “about” or “approximately” as used herein can allow for a degree of variability in a value or range. Moreover, no element or component in this disclosure is intended to be dedicated to the public regardless of whether the element or component is explicitly recited in the following claims.

What is claimed is:

1. A thin-film transistor, comprising:
an oxide semiconductor layer including a channel region and a low-resistance region that has an electric resistance lower than an electric resistance of the channel region;
a gate insulating film provided on the oxide semiconductor layer;
a gate electrode provided on the gate insulating film and opposed to the channel region of the oxide semiconductor layer, the gate electrode including a first electrode layer and a second electrode layer in order from the gate insulating film, the first electrode layer having a first width that is along a channel length and greater than a second width of the second electrode layer along the channel length; and
a source-drain electrode electrically coupled to the low-resistance region of the oxide semiconductor layer.

2. The thin-film transistor according to claim 1, wherein the first electrode layer has a thickness that is less than a thickness of the second electrode layer.

3. The thin-film transistor according to claim 1, wherein the first electrode layer includes:
an opposed region opposed to the second electrode layer; and
a non-opposed region non-opposed to the second electrode layer and having a thickness that is less than a thickness of the opposed region.

4. The thin-film transistor according to claim 1, wherein
the first electrode layer includes a surface opposed to the gate insulating film and having the first width, and
the second electrode layer includes a surface opposed to the first electrode layer and having the second width.

5. The thin-film transistor according to claim 1, wherein a difference between the first width and the second width is one μm or less.

6. The thin-film transistor according to claim 1, wherein the first electrode layer has a thickness that is 100 nm or less.

7. The thin-film transistor according to claim 1, wherein the first electrode layer and the second electrode layer are made of materials different from each other.

8. The thin-film transistor according to claim 7, wherein the first electrode layer includes one or more selected from the group consisting of a titanium alloy, titanium nitride, tungsten, a tungsten alloy, tantalum, and tantalum nitride.

9. The thin-film transistor according to claim 7, wherein the second electrode layer includes one or more selected from the group consisting of aluminum, molybdenum, copper, an aluminum alloy, and a copper alloy.

10. The thin-film transistor according to claim 1, wherein the gate insulating film and the first electrode layer have a same shape in plan view.

11. The thin-film transistor according to claim 10, wherein the gate insulating film and the first electrode layer have side surfaces that form a vertical surface.

12. The thin-film transistor according to claim 1, further comprising a high-resistance film that is in contact with the low-resistance region.

13. A semiconductor unit with a drive circuit, the drive circuit being provided with a thin-film transistor, the thin-film transistor comprising:
an oxide semiconductor layer including a channel region and a low-resistance region that has an electric resistance lower than an electric resistance of the channel region;
a gate insulating film provided on the oxide semiconductor layer;
a gate electrode provided on the gate insulating film and opposed to the channel region of the oxide semiconductor layer, the gate electrode including a first electrode layer and a second electrode layer in order from the gate insulating film, the first electrode layer having a first width that is along a channel length and greater than a second width of the second electrode layer along the channel length; and
a source-drain electrode electrically coupled to the low-resistance region of the oxide semiconductor layer.

14. The semiconductor unit according to claim 13, further comprising a display device driven by the drive circuit.

15. The semiconductor unit according to claim 13, further comprising an image pickup device driven by the drive circuit.

16. An electronic apparatus with a drive circuit, the drive circuit being provided with a thin-film transistor, the thin-film transistor comprising:
an oxide semiconductor layer including a channel region and a low-resistance region that has an electric resistance lower than an electric resistance of the channel region;
a gate insulating film provided on the oxide semiconductor layer;
a gate electrode provided on the gate insulating film and opposed to the channel region of the oxide semiconductor layer, the gate electrode including a first electrode layer and a second electrode layer in order from the gate insulating film, the first electrode layer having a first width that is along a channel length and greater than a second width of the second electrode layer along the channel length; and
a source-drain electrode electrically coupled to the low-resistance region of the oxide semiconductor layer.
